(19) United States
(12) Patent Application Publication
(10) Pub. No.: US 2019/0341338 A1
(43) Pub. Date: Nov. 7, 2019

(54) PREFORMED LEAD FRAME AND LEAD FRAME PACKAGE MADE FROM THE SAME

(71) Applicant: CHANG WAH TECHNOLOGY CO., LTD., Kaohsiung City (TW)

(72) Inventor: Chia-Neng HUANG, Kaohsiung City (TW)

(21) Appl. No.: 16/141,258

(22) Filed: Sep. 25, 2018

(30) Foreign Application Priority Data
May 4, 2018 (TW) 107205847

(51) Int. Cl. H01L 23/495; H01L 23/498; H01L 23/29

(52) U.S. Cl. CPC H01L 23/49537; H01L 23/29; H01L 23/49861; H01L 23/49503

(57) ABSTRACT

A preformed lead frame includes multiple lead frame units, a connection bar connecting the lead frame units and extending along a singulation line, and a molding layer molded over the lead frame units and the connection bar. The molding layer has a lower surface and a plurality of spaced apart elongate grooves indented upwardly from the lower surface. Each of the lead frame units includes a row of spaced-apart leads, each of which has a grooved surface exposed from the lower surface of the molding layer and a grooved soldering surface indented upwardly from the grooved surface and exposed in one of the elongate groove. A lead frame package formed from the preformed lead frame is also disclosed.

### CROSS-REFERENCE TO RELATED APPLICATION

This application claims priority of Taiwanese Utility Model Patent Application No.107205847, filed on May 4, 2018.

### FIELD

The disclosure relates to a preformed lead frame, and more particularly to a preformed lead frame formed with elongated grooves for solder reflowing. This disclosure also relates to a lead frame package made from the preformed lead frame.

### BACKGROUND

Referring to FIG. 1, a conventional flat no-lead package includes a chip seat 11, a plurality of spaced-apart pins 12 that surround the chip seat 11 and that are spaced apart from the chip seat 11, a chip 13 disposed on a top surface of the chip seat 11, a plurality of wires 14 that respectively and electrically connect the chip 13 with the pins 12, and an encapsulant layer 15. Since the flat no-lead package does not have any pins extruding beyond edges of the package, the size of the flat no-lead package can be greatly reduced. However, also due to the lack of outwardly extruding pins, when the flat no-lead package is used and must be soldered to an external circuit board 100, such as a printed circuit board (PCB), insufficient wettable flanks are provided, and so the solder 101 generally has difficulty rising from bottom faces 121 of the pins 12 to side faces 122 of the pins 12 during a subsequent reflow soldering process. This is undesirable as the bonding strength between the flat no-lead package and the external circuit board 100 is strongly related to the contact surface area between the solder 101 and the pins 12. Further, when the solder 101 cannot be seen from the side faces 122 of the pin 12, it is not possible to visually check the condition of the contact between the solder 101 and the pins 12 during the manufacturing process, making quality control more difficult.

Referring to FIG. 2, in order to allow easier reflow of the solder and increase the contact surface between the solder and the pins, such that the strength and reliability of the soldering are improved and the state of the soldering can be more easily observed visually, U.S. Patent Application Publication No. 2016/0148877A1 discloses a method of making a quad flat no-lead (QFN) package with improved contact pins, which involves doubling cutting a lead frame after wire bonding and packaging processes are completed. The method includes cutting a step cut into the pins 12 to form a groove 13 using a first saw width without separating the pins 12, forming an electroplated coating 16 on the pins 12 and the groove 13, and severing the pins 12 completely using a second saw width less than the first saw width so as to produce singlulated QFN packages. Each of the QFN packages is formed with a step cut structure 17 on the side face 122 of each of the pins 12 exposed after the severing. Thus, when the QFN packages are individually soldered to the external circuit board 100, taken example by one QFN package, the step cut structures 17 of the pins 12 may increase wettable flanks of the pins 12, allowing the solder 101 to more easily rise from the bottom faces 121 of the pins 12 to the side faces 122 during the reflow soldering process, which increases the contact surface area between the pins 12 and the solder 101, thus enhancing the bonding strength between the QFN package and the external circuit board 100 and allowing the condition of soldering to be visually checked. However, in order to form the step cut structures 17 of the pins 12, two cuttings must be done after packaging, which not only increases manufacturing time but also increases manufacturing costs.

### SUMMARY

Therefore, an object of the disclosure is to provides a preformed lead frame that can alleviates some of the drawbacks of the prior art. A lead frame package made from the preformed lead frame unit is also provided.

According to one aspect of the disclosure, a preformed lead frame includes at least two lead frame units, at least one connection bar extending along a singulation line and connecting between the at least two lead frame units, and a molding layer molded over the at least two lead frame units and the at least one connection bar. The molding layer has an upper surface, a lower surface opposite to the upper surface, and a plurality of spaced apart elongate grooves indented upwardly from the lower surface.

Each of the at least two lead frame units includes a row of spaced-apart leads. The leads of one of the at least two lead frame units are respectively and alignedly connected to the leads of the other one of the at least two lead frame units via the connection bar. Each of the leads has a wire connecting surface exposed from the upper surface of the molding layer, a grooved surface opposite to the wire connecting surface and exposed from the lower surface of the molding layer, and a grooved soldering surface indented upwardly from the grooved surface and exposed in one of the elongate grooves.

Each of the elongate grooves extends through the singulation line and has two opposite groove ends respectively bordered by the grooved surfaces of two of the leads that are alignedly connected to each other. Each of the elongate grooves has a first width at the singulation line, and two second widths at the two opposite groove ends. The first width is larger than the second widths.

According to another aspect of the disclosure, a lead frame package includes a molding layer, a lead frame unit and a chip unit.

The molding layer has an upper surface, a lower surface opposite to the upper surface, a lateral surface interconnecting the upper and lower surfaces, a framed portion extending from the upper surface to the lower surface, and a surrounding frame section disposed around the framed portion and extending from the upper surface to the lower surface. The framed portion and the surrounding frame section share each of the upper and lower surfaces.

The lead frame unit includes a plurality of spaced-apart leads embedded in the molding layer. Each of the leads has a wire connecting surface exposed from the upper surface of the molding layer, a grooved surface opposite to the wire connecting surface and exposed from the lower surface of the molding layer, a side face exposed from the lateral surface of the molding layer and extending downwardly from the wire connecting surface, and a grooved soldering surface indented upwardly from the grooved surface and extending sideward to connect the side face. The grooved soldering surface of each of the leads cooperates with the molding layer to define a solder-receiving groove. The solder-receiving groove has a first width measured at a line of a junction of the lateral surface and the lower surface of the molding layer, and a second width measured at a line of a junction of the grooved surface and the grooved soldering surface of a corresponding one of the leads, the first width being larger than the second width.

The chip unit includes a chip disposed on the framed portion of the molding layer, and a plurality of wires connected between the chip and the leads.

### BRIEF DESCRIPTION OF THE DRAWINGS

Other features and advantages of the disclosure will become apparent in the following detailed description of the embodiment with reference to the accompanying drawings, of which:

FIG. 1 is a schematic view of a conventional flat no-lead package;

FIG. 2 is a schematic view illustrating consecutive steps for making a conventional QFN package;

FIG. 3 is a perspective top view of an embodiment of a lead frame package according to the disclosure;

FIG. 4 is a perspective bottom view of the embodiment;

FIG. 5 is a sectional view taken along the line V-V of FIG. 3;

FIG. 6 is a perspective top view of an embodiment of a preformed lead frame according to the disclosure;

FIGS. 7A to 7E are schematic views illustrating consecutive steps for producing the embodiment of the preformed lead frame;

FIG. 7F is a partial magnified view of FIG. 7E;

FIG. 8 is a sectional view of the embodiment of the preformed lead frame further having an electroplating layer.

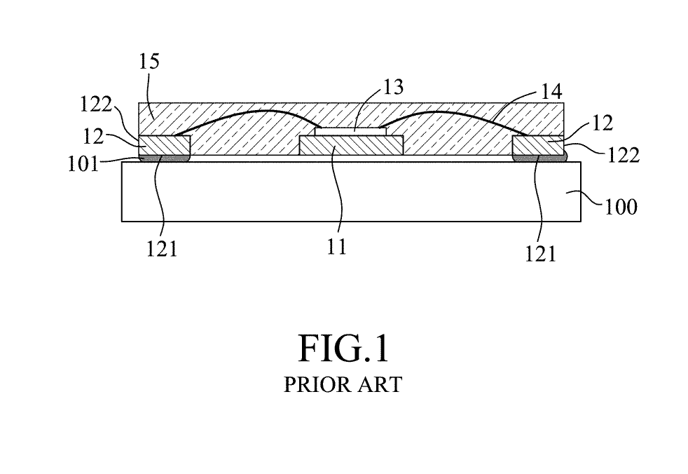

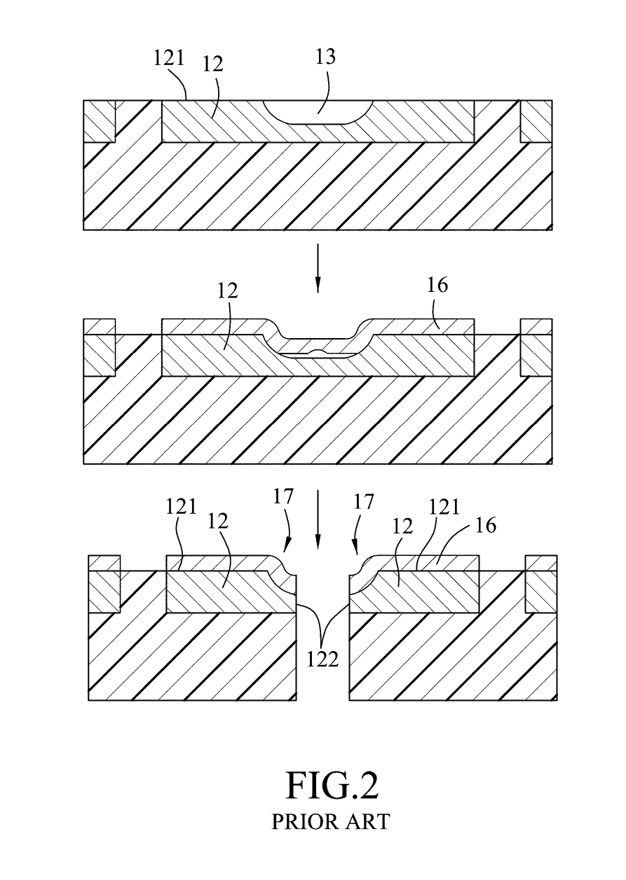

### DETAILED DESCRIPTION

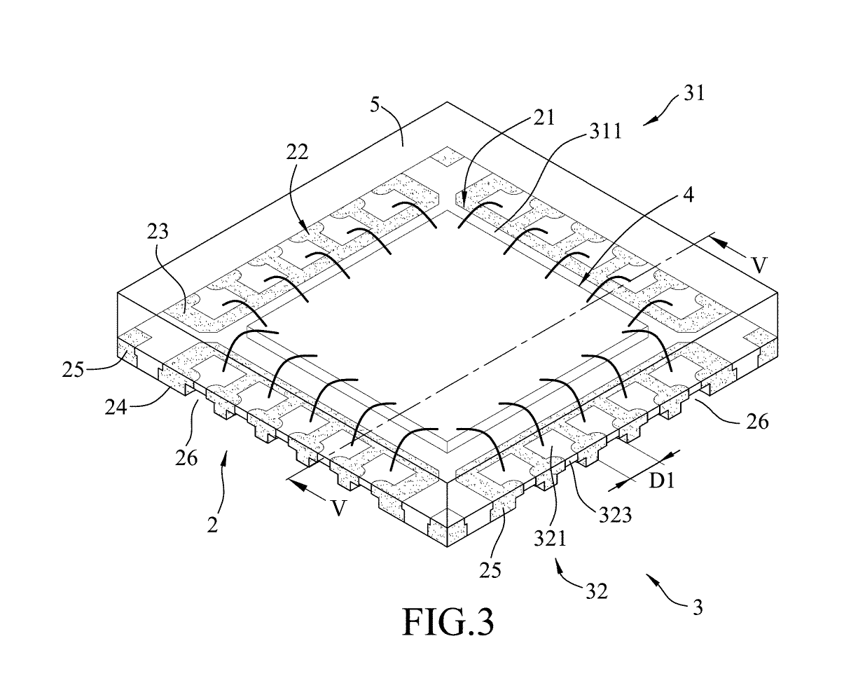

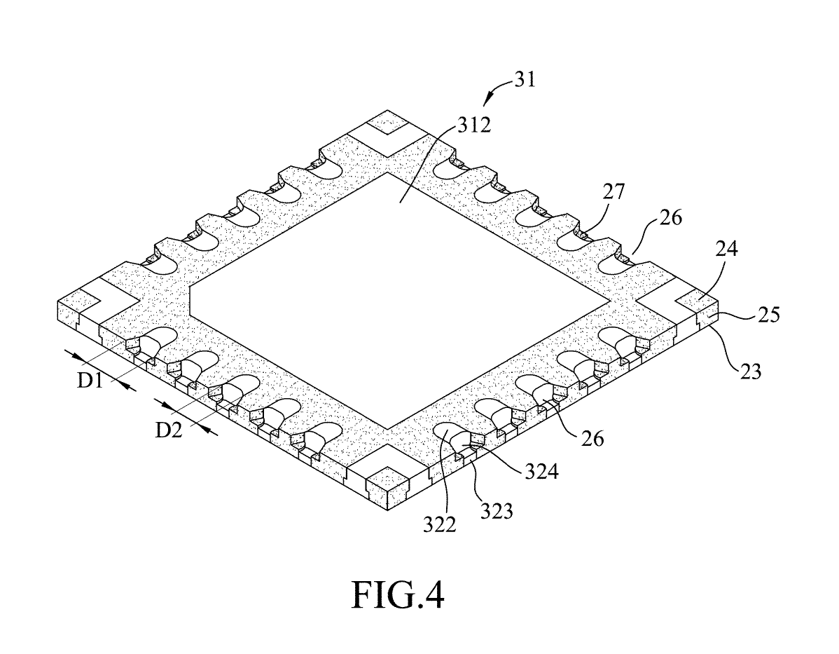

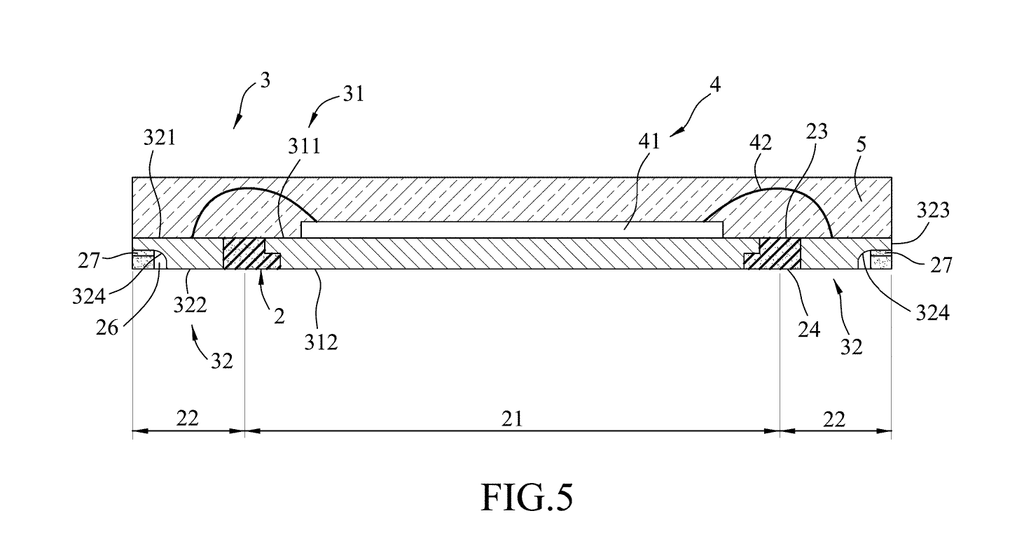

Referring to FIGS. 3 to 5, FIG. 3 is a perspective top view of an embodiment of a lead frame package according to the disclosure, FIG. 4 is a bottom perspective view of the embodiment, and FIG. 5 is a sectional view taken along the line V-V of FIG. 3.

The embodiment includes a molding layer 2, a lead frame unit 3, a chip unit 4 and an encapsulant layer 5.

The molding layer 2 may be made of an electrically insulating polymer, and has an upper surface 23, a lower surface 24 opposite to the upper surface 23, a lateral surface 25 interconnecting the upper and lower surfaces 23, 24, a framed portion 21 extending from the upper surface 23 to the lower surface 24, and a surrounding frame section 22 disposed around the framed portion 21 and extending from the upper surface 23 to the lower surface 24. The framed portion 21 and the surrounding frame section 22 share each of the upper and lower surfaces 23, 24.

The lead frame unit 3 includes a plurality of spaced-apart leads 32 that are electrically independent of each other and embedded in the surrounding frame portion 22.

The lead frame package further includes a die pad 31 embedded in the framed portion 21 of the molding layer 2. The die pad 31 has a pad top surface 311 exposed from and coplanar with the upper surface 23 of the molding layer 2 and a pad bottom surface 312 exposed from and coplanar with the lower surface 24 of the molding layer 2. In this embodiment, the die pad 31 constitutes a portion of the lead frame unit 3, and the leads 32 are spaced apart from the die pad 31. The die pad 31 and the leads 32 may be made of the same electrically conducting material, examples include, but are not limited to, cooper alloys or iron-nickel alloys.

Each of the leads 32 has a wire connecting surface 321 exposed from the upper surface 23 of the molding layer 2, a grooved surface 322 opposite to the wire connecting surface 321 and exposed from the lower surface 24 of the molding layer 2, a side face 323 exposed from the lateral surface 25 of the molding layer 2 and extending downwardly from the wire connecting surface 321, and a grooved soldering surface 324 indented upwardly from the grooved surface 322 and extending sideward to connect the side face 323. The grooved soldering surface 324 of each of the leads 32 cooperates with the molding layer 2 to define a solder-receiving groove 26, and is exposed from the solder-receiving groove 26. The soldering-grooves 26 independently penetrate from the lateral surface 25 through to the lower surface 24.

In one form, the wire connecting surface 321 of each of the 32 is coplanar with the upper surface 23 of the molding layer 2. The grooved surface 322 of each of the leads 32 is coplanar with the lower surface 24 of the molding layer 2. The side face 323 of each of the leads 32 is coplanar with the lateral surface 25 of the molding layer 2.

In particular, each of the solder-receiving grooves 26 has a first width D1 measured at a line of a junction of the lateral surface 25 and the lower surface 24 of the molding layer 2, and a second width measured at a line of a junction of the grooved surface 322 and the grooved soldering surface 324 of a corresponding one of the leads 32. The first width D1 is larger than the second width D2.

The solder-receiving grooves 26 may have, but are not limited to, a cross-section extending from the grooved soldering surface 324 to the side face 323 of one of the leads 32 that is trapezoid, semi-circular or semi-elliptic, as long as the first width D1 is the maximum width of the soldering hole 26. In this embodiment, as an example, the cross-section of the solder-receiving grooves 26 is trapezoid.

The molding layer 2 further includes a plurality of step formations 27, each of the step formations 27 protruding from the surrounding frame section 22 into a corresponding one of the solder-receiving grooves 26 of the leads 32 and onto a corresponding one of the grooved soldering surfaces 324 of the leads 32. Each of the step formations 27 has a thickness, which is measured from the grooved soldering surface 324 of a corresponding one of the leads 32 and is smaller than a half of a maximum depth of a corresponding one of the solder-receiving grooves 26 of the leads 32 measured from the lower surface 24 of the molding layer 2.

The chip unit 4 includes a chip 41 disposed on the framed portion 21 of the molding layer 2, and a plurality of wires 42 connected between the chip 41 and the leads 32.

The encapsulant layer 5 encapsulates the chip unit 4, and is made of an electrically insulating polymer that may be transparent. In this embodiment, as an example, the encapsulant layer 5 is made of a transparent material.

In the embodiment of the lead frame package according to this disclosure, because the first width D1 of each of the solder-receiving grooves 26 is the maximum width of the solder-receiving groove 26, the visible area for inspection after soldering is increased. Furthermore, the configuration of the solder-receiving grooves 26 allows a portion of the solder proximal to the lateral surface 25 of the molding layer 2 to be hemispherical due to cohesion of the solder, thereby easing visual inspection of soldering conditions. Each of the step formations 27 also form a step cut structure with the corresponding one of the solder-receiving grooves 26 which aids the solder in rising in the solder-receiving groove 26, making it more visible from the lateral surface 25.

In the following, the embodiment of a preformed lead frame 200A applicable to production of the aforementioned lead frame package is illustrated. The lead frame package is produced from performing the bonding and packaging of a chip and cutting on the preformed lead frame 200A.

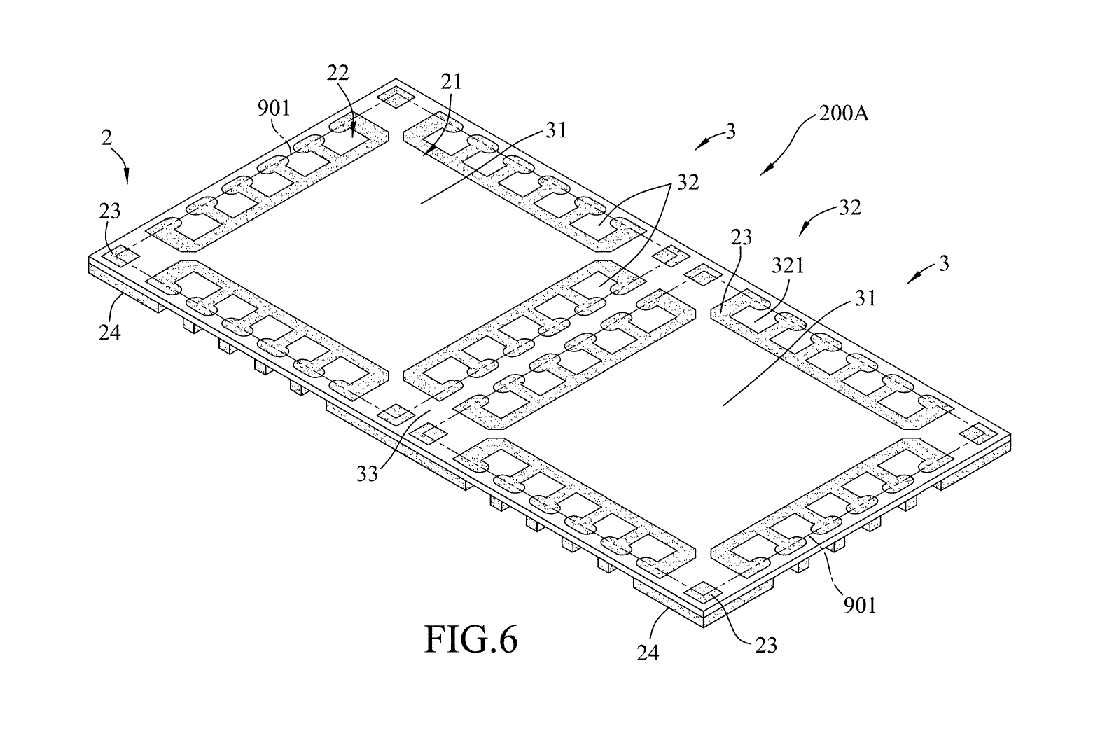

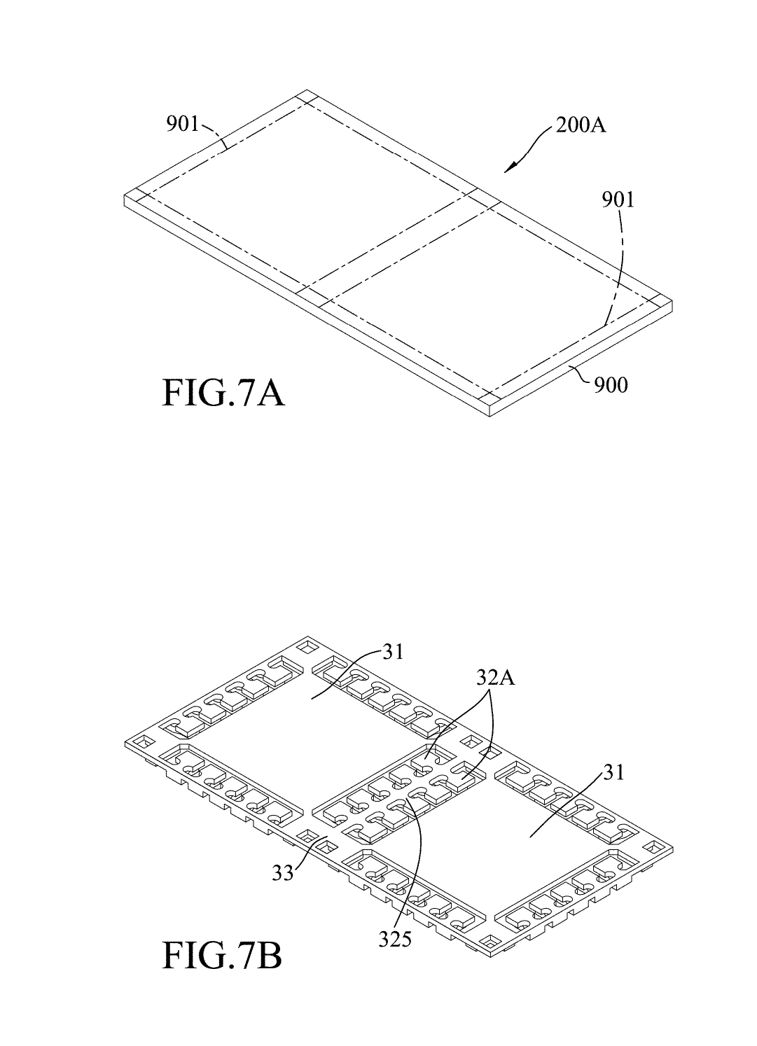

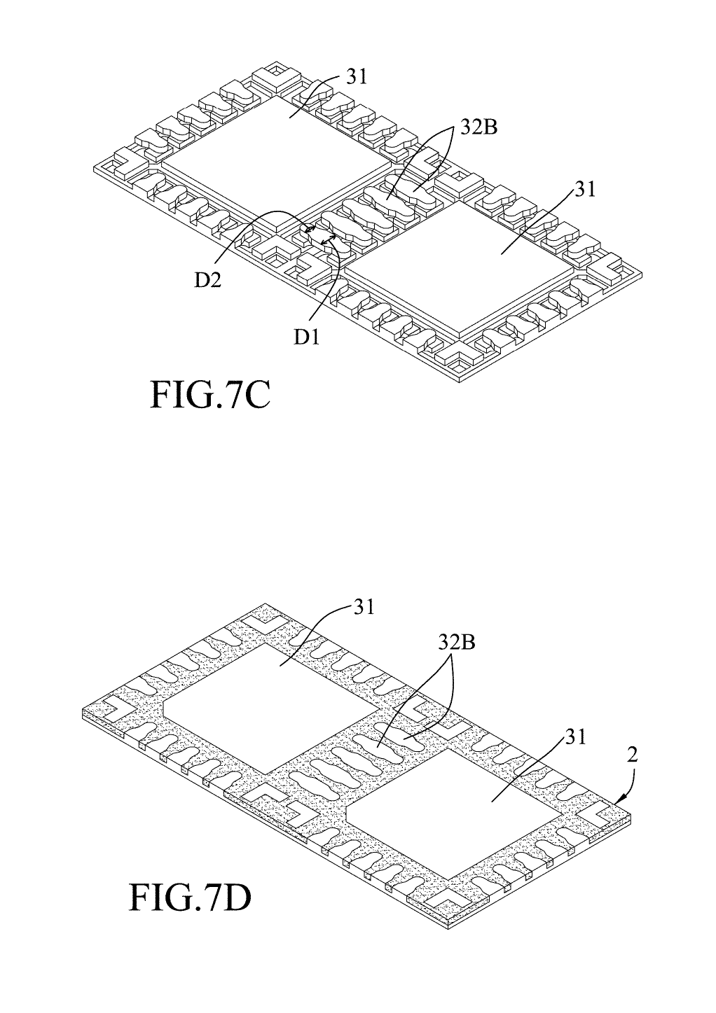

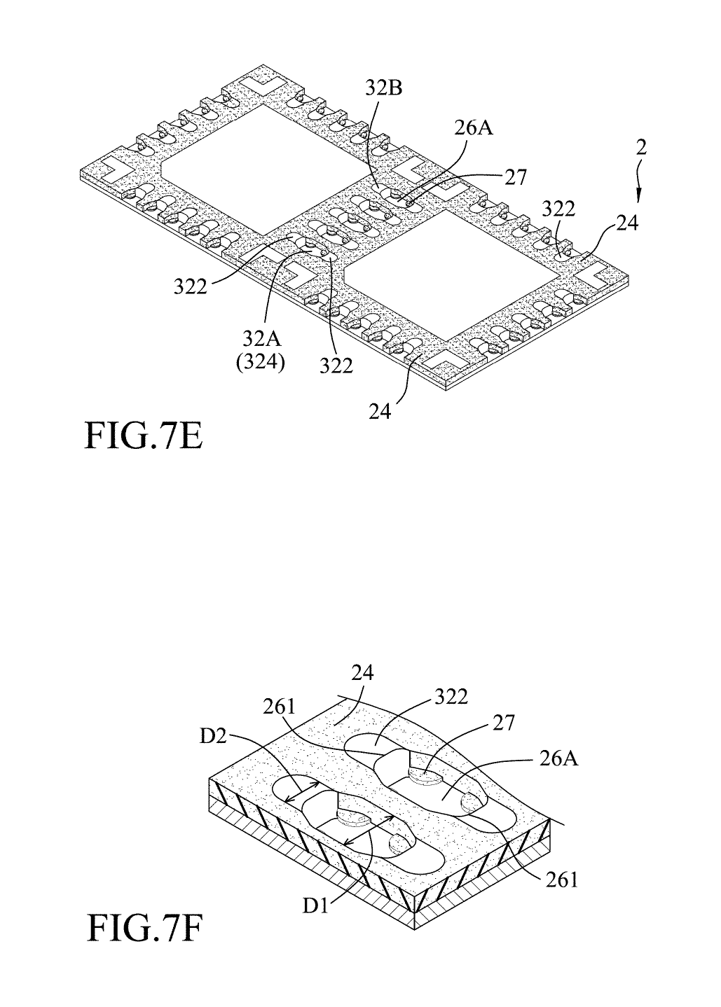

Referring to FIGS. 6 and 7E, the embodiment of the preformed lead frame 200A includes the molding layer 2, at least two of the lead frame units 3, and at least one connection bar 33 extending along at least one singulation line 901 and connecting the at least two lead frame units 3. In this embodiment, as an example, the preformed lead frame 200A includes two of the lead frame units 3, one of the connection bar 33 and two of the singulation lines 901 respectively defining boundaries of the two lead frame units 3.

The molding layer 2 is molded over the two lead frame units 3 and the connection bar 33, and has a plurality of spaced apart elongate grooves 26A indented upwardly from the lower surface 24, and a plurality of the step formations 27. Each of the elongate grooves 26A extends through the two singulation lines 901 and has two opposite groove ends 261 respectively bordered by the grooved surfaces 322 of two of the leads 32 that are alignedly connected to each other. Each of the elongate grooves 26A has a first width D1 along the two singulation lines 901 which the elongate groove 26A extends through and two second widths D2 at the two opposite groove ends 261. The first width D1 is larger than the second widths D2, and is the maximum width of the elongated grooves 26A.

Each of the step formations 27 protrudes from the molding layer 2 into one of the elongate grooves 26A. Each of the step formations 27 has a thickness smaller than a half of a maximum depth of a corresponding one of the elongate grooves 26A measured from the lower surface 24 of the molding layer 2. The thickness of each of the step formations 27 is measured along a direction of the depth of a corresponding one of the elongate grooves 26A.

Each of the two lead frame units 3 includes a row of the spaced-apart leads 32. The leads 32 of each of the two lead frame units 3 are respectively and alignedly connected to the leads 32 of another one of the lead frame units 3 via the connection bar 33. Each of the leads 32 has the wire connecting surface 321 exposed from the upper surface 23 of the molding layer 2; the grooved surface 322 opposite to the wire connecting surface 321 and exposed from the lower surface 24 of the molding layer 2; and the grooved soldering surface 324 indented upwardly from the grooved surface 322, that cooperatively defines the elongate groove 26A with the molding layer 2, and is exposed in the elongate groove 26A.

In one form, the wire connecting surface 321 of each of the leads 32 is coplanar with the upper surface 23 of the molding layer 2. The grooved surface 322 of each of the leads 32 is coplanar with the lower surface 24 of the molding layer 2.

The preformed lead frame 200A also includes two of the die pads 31. Each of the die pads 31 is embedded in each of the framed portions 21 of the molding layer 2. Each of the die pads 31 has the pad top surface 311 exposed from and coplanar with the upper surface 23 of the molding layer 2 and the pad bottom surface 312 exposed from and coplanar with the lower surface 24 of the molding layer 2.

Specifically, the preformed lead frame 200A is produced using etching and preforming.

Referring to FIG. 7A, production of the preformed lead frame 200A starts with providing an electrically conductive substrate 900, which may be made from copper alloys or iron-nickel alloys. The two singulation lines 901 respectively extend through the surrounding frame sections 22 of the molding layer 2. Then, etching is performed on the substrate 900. Referring to FIGS. 7B and 7C, unnecessary portions of the substrate 900 are removed using etching. From etching, the die pad 31 is preformed on the substrate 900 and a plurality of first lead-forming portions 32A and a plurality of second lead-forming portions 32B are respectively formed on the front and back surface of the substrate 900. Each of the first lead-forming portions 32A and the second lead-forming portions 32B extends through the two simulation lines 901. In particular, each first lead-forming portion 32A and second lead-forming portion 32B extend respectively from the front and back surfaces of one of the lead frame units 3 across the connection bar 33 to the other one of the lead frame units 3 and correspond to each other in position. Each of the first lead-forming portions 32A has two neck portions 325 that are respectively located at the intersections of the two simulation lines 901 and each of the first lead-forming portions 32A. Each of the neck portions 325 has a width that is the minimum width of a corresponding one of the first lead-forming portions 32A. Each of the second lead-forming portions 32B has first widths D1 respectively along the two singulation lines 901 and the second widths D2 proximal to the die pads 31. The first widths D1 are larger than the second widths D2, and are the maximum width of the second lead-forming portions 32B. The second lead-forming portions 32B are exposed among the neck portions 325 of the first lead-forming portions 32A.

Referring to FIG. 7D, the substrate 900 that has gone through the etching process is then sandwiched within a mold (not shown), and then a molding material is injected into the mold, filling the spaces formed in the substrate 900 after etching. The molding material may be an electrically insulating packaging material such as epoxy resin. The molding material is solidified to form the molding layer 2, thereby obtaining a semi-finished product. FIG. 7D shows the back surface of the semi-finished product.

Then, etching is performed on the back surface of the semi-finished product. Referring to FIGS. 6, 7E and 7F, FIG. 7E shows the back view of the preformed lead frame 200A after etching, FIG. 7D is a partial magnified view of FIG. 7E, and FIG. 6 is the front view of FIG. 7E.

A portion of the second lead-forming portions 32B is removed by etching to expose the first lead-forming portion 32A to form the elongate grooves 26A and the step formations 27 disposed within the elongate grooves 26A. The preformed lead frame 200A shown in FIG. 7E is then obtained. In particular, what remains of the first and second lead-forming portions 32A and 32B after etching cooperatively form the leads 32, and the portions of the first lead-forming portion 32A exposed from the elongate grooves 26A respectively form the grooved soldering surfaces 324.

Referring to FIG. 6, the preformed lead frame 200A can then be used to perform the bonding of the chip 41, the wire bonding and the packaging, and then cut along the singulation lines 901 shown in FIG. 6 to obtain the lead frame package shown in FIG. 3.

Since the second lead-forming portions 32B of the preformed lead frame 200A have maximum widths along the two singulation lines 901, the elongate grooves 26A formed after etching would also have a maximum width along the two singulation lines 901. Thus, after cutting is done along the singulation lines 901, the solder-receiving grooves 26 formed from the elongate grooves 26A would also have a maximum width (the first width D1) where it is cut, forming solder-receiving grooves 26 with a maximum viewing angle on the side of the lead frame package.

In some embodiments, depending on different requirements, the solder-receiving groove 26 may not contain the step formation 27. When this is the case, the first lead-forming portions 32A would not have the neck portion 325, and instead may have the same shape as the second lead-forming portions 32B so that the first and second lead-forming portions 32A, 32B can be formed simultaneously during etching, as long as the widths of the first and second lead-forming portions 32A and 32B at the intersections of the singulation lines 901 and themselves are respectively the maximum widths of the first and second lead-forming portions 32A and 32B.

Further, when the lead frame package is of a smaller dimension or heat dissipation is of lower importance, the framed portions 21 of the molding layer 2 may serve as the die pads 31 and the chips 41 may be directly disposed thereon.

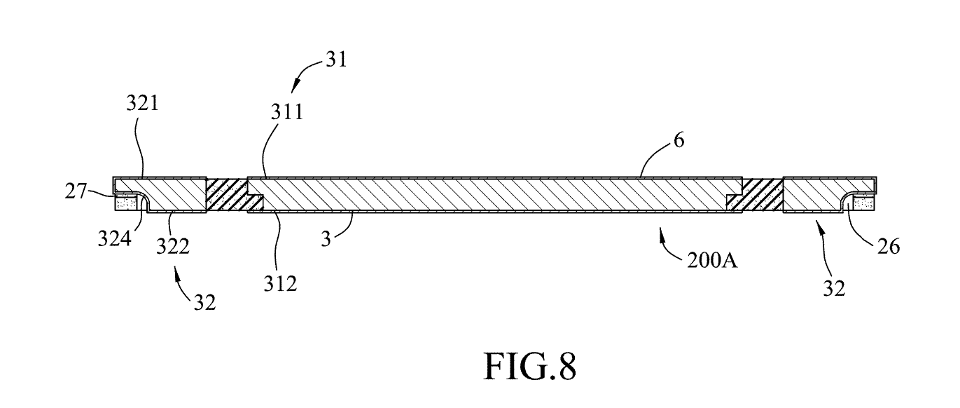

Referring to FIG. 8, in some embodiments, a electroplating process may be further conducted after forming the preformed lead frame 200A shown in FIG. 7E, such that one or more electroplating layers 6 may further be formed before the packaging process. FIG. 8 shows one electroplating layer 6 as an example. The electroplating layer 6 may be made from a material different from that of the leads 32 and the die pad 31. The electroplating layer 6 may be made from a metal, for example, nickel, palladium, silver, or gold, or alloys thereof. The electroplating layer 6 can improve the wettability between the solder and the leads 32 such that the solder can more easily rise on the grooved soldering surfaces 324, thereby increasing the connections of the preformed lead frame 200A with the electrically insulating polymer used in subsequent packaging and with the wires 42.

In view of the foregoing, due to the structural design of the preformed lead frame 200A, which is formed with the preformed elongate grooves 26A and the step formations 27 formed in the elongate grooves 26A, with the preformed elongate grooves 26A having maximum width along the two singulation lines 901, the preformed lead frame 200A has the elongate grooves 26A with a maximum viewing angle. Furthermore, the lead frame package formed from the cutting the preformed lead frame 200A has the solder-receiving grooves 26 with a maximum width where it is cut, i.e., along the corresponding singulation line 901. Each of the solder-receiving grooves 26 can define a step cut structure with the step formation 27, can allow the surface of the corresponding lead 32 to be exposed and has a maximum width at the contact between the lateral surface 25 and the lower surface 24 of the molding layer 2. Thus, not only is the visible area increased for later soldering inspections, the ease of inspection is also improved using the step cut structure, as the step cut structure encourages reflow of the solder so that the solder rises from the solder-receiving grooves 26 to be more exposed on the lateral surface 25.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what is considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A preformed lead frame, comprising:
at least two lead frame units;
at least one connection bar extending along a singulation line and connecting between said at least two lead frame units; and
a molding layer molded over said at least two lead frame units and said at least one connection bar, and having an upper surface, a lower surface opposite to said upper surface, and a plurality of spaced apart elongate grooves indented upwardly from said lower surface;
each of said at least two lead frame units including a row of spaced-apart leads, said leads of one of said at least two lead frame units being respectively and alignedly connected to said leads of the other one of said at least two lead frame units via said connection bar, each of said leads having a wire connecting surface exposed from said upper surface of said molding layer, a grooved surface opposite to said wire connecting surface and exposed from said lower surface of said molding layer, and a grooved soldering surface indented upwardly from said grooved surface and exposed in one of said elongate grooves;
each of said elongate grooves extending through said singulation line and having two opposite groove ends respectively bordered by said grooved surfaces of two of said leads that are alignedly connected to each other, each of said elongate grooves having a first width at said singulation line, and two second widths at said two opposite groove ends, said first width being larger than said second widths.

2. The preformed lead frame of claim 1, wherein said wire connecting surface of each of said leads is coplanar with said upper surface of said molding layer, said grooved surface of each of said leads being coplanar with said lower surface of said molding layer.

3. The preformed lead frame of claim 1 wherein said molding layer further includes a plurality of step formations, each of said step formations protruding from said molding layer into one of said elongate grooves.

4. The preformed lead frame of claim 3, wherein each of said step formations has a thickness being smaller than a half of a maximum depth of a corresponding one of said elongate grooves measured from said lower surface of said molding layer, the thickness of each of said step formations being measured along a direction of the depth of a corresponding one of said elongate grooves.

5. The preformed lead frame of claim 1, further comprising a plurality of die pads embedded in said molding layer, each of said die pads having a pad top surface exposed from and coplanar with said upper surface of said molding layer and a pad bottom surface exposed from and coplanar with said lower surface of said molding layer.

6. The preformed lead frame of claim 5, further comprising an electroplating layer that is formed on said wire connecting surface, said grooved surface and said grooved soldering surface of each of said leads, and that is formed on said pad top surface and said pad bottom surface of each of said die pads.

7. The preformed lead frame of claim 6, wherein said electroplating layer is made from a material different from that of said leads.

8. The preformed lead frame of claim 7, wherein said electroplating layer is made from a material different from that of said die pad.

9. A lead frame package, comprising:
a molding layer having an upper surface, a lower surface opposite to said upper surface, a lateral surface interconnecting said upper and lower surfaces, a framed portion extending from said upper surface to said lower surface, and a surrounding frame section disposed around said framed portion and extending from said upper surface to said lower surface, said framed portion and said surrounding frame section sharing each of said upper and lower surfaces;
a lead frame unit including a plurality of spaced-apart leads embedded in said molding layer, each of said leads having a wire connecting surface exposed from said upper surface of said molding layer, a grooved surface opposite to said wire connecting surface and exposed from said lower surface of said molding layer, a side face exposed from said lateral surface of said molding layer and extending downwardly from said wire connecting surface, and a grooved soldering surface indented upwardly from said grooved surface and extending sideward to connect said side face, said grooved soldering surface of each of said leads cooperating with said molding layer to define a solder-receiving groove, said solder-receiving groove having a first width measured at a line of a junction of said lateral surface and said lower surface of said molding layer, and a second width measured at a line of a junction of said grooved surface and said grooved soldering surface of a corresponding one of said leads, said first width being larger than said second width; and
a chip unit including a chip disposed on said framed portion of said molding layer, and a plurality of wires connected between said chip and said leads.

10. The lead frame package of claim 9, wherein said wire connecting surface of each of said leads is coplanar with said upper surface of said molding layer, said grooved surface of each of said leads being coplanar with said lower surface of said molding layer, and said side face of each of said leads being coplanar with said lateral surface of said molding layer.

11. The lead frame package of claim 9, wherein said molding layer further includes a plurality of step formations, each of said step formations protruding from said surrounding frame section into a corresponding one of said solder-receiving grooves of said leads and onto a corresponding one of said grooved soldering surfaces of said leads.

12. The lead frame package of claim 11, wherein each of said step formations has a thickness measured from said grooved soldering surface of a corresponding one of said leads, said thickness being smaller than a half of a maximum depth of a corresponding one of said solder-receiving grooves of said leads measured from said lower surface of said molding layer.

13. The lead frame package of claim 9, further comprising a die pad embedded in said framed portion, said die pad having a pad top surface exposed from and coplanar with said upper surface of said molding layer and a pad bottom surface exposed from and coplanar with said lower surface of said molding layer.

14. The lead frame package of claim 13, further comprising an electroplating layer that is formed on said wire connecting surface, said grooved surface, and said grooved soldering surface of each of said leads and that is formed on said pad top surface and said pad bottom surface of said die pad.

15. The lead frame package of claim 14, wherein said electroplating layer is made from a material different from that of said leads.

16. The lead frame package of claim 14, wherein said electroplating layer is made from a material different from that of said die pad.

17. The lead frame package of claim 9, further comprising an encapsulant layer that encapsulates said chip unit.
